(19) United States
(12) Patent Application Publication
(10) Pub. No.: US 2010/0102352 A1
(43) Pub. Date: Apr. 29, 2010

(54) III-Nitride Semiconductor Light Emitting Device

(75) Inventors: Chang Tae Kim, Seongnam-si (KR); Min Gyu Na, Gimje-si (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gumi-city (KR)

(21) Appl. No.: 12/647,750

(22) Filed: Dec. 28, 2009

Related U.S. Application Data
(63) Continuation of application No. PCT/KR2009/005707, filed on Oct. 7, 2009.

(30) Foreign Application Priority Data
Oct. 24, 2008 (KR) 10-2008-0104569

(51) Int. Cl. H01L 33/00

(52) U.S. Cl. 257/98; 257/103; 257/E33.074

(57) ABSTRACT

The present disclosure relates to a III-nitride semiconductor light-emitting device including a substrate with a scattering zone formed therein, and a plurality of III-nitride semiconductor layers including a first III-nitride semiconductor layer formed over the substrate and having a first conductivity type, a second III-nitride semiconductor layer formed over the first III-nitride semiconductor layer and having a second conductivity type different from the first conductivity type, and an active layer disposed between the first III-nitride semiconductor layer and the second III-nitride semiconductor layer and generating light by recombination of electrons and holes.

### CROSS-REFERENCE TO RELATED APPLICATIONS

This application is a continuation of PCT Application No. PCT/KR2009/005707 filed on Oct. 7, 2009, which claims the benefit and priority to Korean Patent Application No. 10-2008-0104569, filed Oct. 24, 2008. The entire disclosures of the applications identified in this paragraph are incorporated herein by reference.

### FIELD

The present disclosure relates generally to a III-nitride semiconductor light-emitting device, and more particularly, to a III-nitride semiconductor light-emitting device which includes a substrate with a scattering zone formed therein to improve light extraction efficiency. The III-nitride semiconductor light-emitting device means a light-emitting device such as a light-emitting diode including a compound semiconductor layer composed of Al₍ₓ₎Ga_{(y)}In_{(1-x-y)}N (0≦x1, 0≦y≦1, 0≦x+y≦1), and may further include a material composed of other group elements, such as SiC, SiN, SiCN and CN, and a semiconductor layer made of such materials.

### BACKGROUND

This section provides background information related to the present disclosure which is not necessarily prior art.

FIG. 1 is a view of an example of a conventional III-nitride semiconductor light-emitting device. The III-nitride semiconductor light-emitting device includes a substrate 100, a buffer layer 200 grown on the substrate 100, an n-type III-nitride semiconductor layer 300 grown on the buffer layer 200, an active layer 400 grown on the n-type III-nitride semiconductor layer 300, a p-type III-nitride semiconductor layer 500 grown on the active layer 400, a p-side electrode 600 formed on the p-type III-nitride semiconductor layer 500, a p-side bonding pad 700 formed on the p-side electrode 600, an n-side electrode 800 formed on the n-type III-nitride semiconductor layer 300 exposed by mesa-etching the p-type III-nitride semiconductor layer 500 and the active layer 400, and an optional protection film 900.

In the case of the substrate 100, a GaN substrate can be used as a homo-substrate. A sapphire substrate, a SiC substrate or a Si substrate can be used as a hetero-substrate. However, any type of substrate that can have a nitride semiconductor layer grown thereon can be employed. In the case that the SiC substrate is used, the n-side electrode 800 can be formed on the surface of the SiC substrate.

The nitride semiconductor layers epitaxially grown on the substrate 100 are usually grown by metal organic chemical vapor deposition (MOCVD).

The buffer layer 200 serves to overcome differences in lattice constant and thermal expansion coefficient between the hetero-substrate 100 and the nitride semiconductor layers. U.S. Pat. No. 5,122,845 describes a technique of growing an AlN buffer layer with a thickness of 100 to 500 Å on a sapphire substrate at 380 to 800° C. In addition, U.S. Pat. No. 5,290,393 describes a technique of growing an Al₍ₓ₎Ga₍₁₋ₓ₎N (0≦x<1) buffer layer with a thickness of 10 to 5000 Å on a sapphire substrate at 200 to 900° C. Moreover, U.S. Publication No. 2006/154454 describes a technique of growing a SiC buffer layer (seed layer) at 600 to 990° C., and growing an In₍ₓ₎Ga₍₁₋ₓ₎N (0<x≦1) thereon. In particular, it is provided with an undoped GaN layer with a thickness of 1 micron to several microns (μm) on the AlN buffer layer, the Al₍ₓ₎Ga₍₁₋ₓ₎N (0≦x<1) buffer layer or the SiC/In₍ₓ₎Ga₍₁₋ₓ₎N (0<x≦1) layer,

In the n-type nitride semiconductor layer 300, at least the n-side electrode 800 formed region (n-type contact layer) is doped with a dopant. Some embodiments, the n-type contact layer is made of GaN and doped with Si. U.S. Pat. No. 5,733,796 describes a technique of doping an n-type contact layer at a target doping concentration by adjusting the mixture ratio of Si and other source materials.

The active layer 400 generates light quanta by recombination of electrons and holes. For example, the active layer 400 contains In₍ₓ₎Ga₍₁₋ₓ₎N (0<x≦1) and has a single layer or multi-quantum well layers.

The p-type nitride semiconductor layer 500 is doped with an appropriate dopant such as Mg, and has p-type conductivity by an activation process. U.S. Pat. No. 5,247,533 describes a technique of activating a p-type nitride semiconductor layer by electron beam irradiation. Moreover, U.S. Pat. No. 5,306,662 describes a technique of activating a p-type nitride semiconductor layer by annealing over 400° C. U.S. Publication No. 2006/157714 describes a technique of endowing a p-type nitride semiconductor layer with p-type conductivity without an activation process, by using ammonia and a hydrazine-based source material together as a nitrogen precursor for growing the p-type nitride semiconductor layer.

The p-side electrode 600 is provided to facilitate current supply to the p-type nitride semiconductor layer 500. U.S. Pat. No. 5,563,422 describes a technique associated with a light-transmitting electrode composed of Ni and Au formed over almost the entire surface of the p-type nitride semiconductor layer 500 and in ohmic-contact with the p-type nitride semiconductor layer 500. In addition, U.S. Pat. No. 6,515,306 describes a technique of forming an n-type superlattice layer on a p-type nitride semiconductor layer, and forming a light-transmitting electrode made of indium tin oxide (ITO) thereon.

The p-side electrode 600 can be formed so thick as to not transmit but rather to reflect light toward the substrate 100. This technique is called the flip chip technique. U.S. Pat. No. 6,194,743 describes a technique associated with an electrode structure including an Ag layer with a thickness over 20 nm, a diffusion barrier layer covering the Ag layer, and a bonding layer containing Au and Al, and covering the diffusion barrier layer.

The p-side bonding pad 700 and the n-side electrode 800 are provided for current supply and external wire bonding. U.S. Pat. No. 5,563,422 describes a technique of forming an n-side electrode with Ti and Al.

The optional protection film 900 can be made of SiO₂.

The n-type nitride semiconductor layer 300 or the p-type nitride semiconductor layer 500 can be constructed as a single layer or as plural layers. Vertical light-emitting devices are introduced by separating the substrate 100 from the nitride semiconductor layers using a laser technique or wet etching.

FIG. 2 is a view of one example of a semiconductor light-emitting device described in U.S. Pat. No. 6,657,236. A rough surface 310 having a different refractive index is formed in a III-nitride semiconductor layer 300 to scatter light and thus to improve external quantum efficiency.

FIG. 3 is a view of another example of the semiconductor light-emitting device described in U.S. Pat. No. 6,657,236. A material layer 120 (SiO₂ or nitride layer) with a different refractive index is formed on a substrate 100 with convex portions 110 formed thereon, and a III-nitride semiconductor layer 300 is formed on the resulting structure, thereby improving external quantum efficiency.

FIG. 4 is a view of an example of a method for fabricating a semiconductor light-emitting device described in U.S. Pat. Publication No. 2008/121906. Grooves 130 are formed in a substrate 100 by a laser, and then grooves 140 are further formed in the substrate 100. As such, the light-emitting device can be easily divided into individual chips. For example, the laser is irradiated from the opposite side of the substrate 100, such as the groove 130-formed side to the substrate 100, and focused on the groove-140-to-be-formed region, thereby forming the grooves 140.

FIG. 5 is a view of an example of a method for fabricating a semiconductor light-emitting device described in Japanese Pat. Publication No. H11-163403. Grooves 130 are formed in a process-damaged layer 110 by laser irradiation. As such, the light-emitting device can be divided into individual chips.

### SUMMARY

This section provides a general summary of the disclosure, and is not a comprehensive disclosure of its full scope or all of its features.

There is provided a III-nitride semiconductor light-emitting device, including a substrate with a scattering zone formed therein; and a plurality of III-nitride semiconductor layers including a first III-nitride semiconductor layer formed over the substrate and having a first conductivity type, a second III-nitride semiconductor layer formed over the first III-nitride semiconductor layer and having a second conductivity type different from the first conductivity type, and an active layer disposed between the first III-nitride semiconductor layer and the second III-nitride semiconductor layer and generating light by recombination of electrons and holes.

According to a III-nitride semiconductor light-emitting device of the present disclosure, light extraction efficiency of the light-emitting device can be improved.

In an embodiment, according to a III-nitride semiconductor light-emitting device of the present disclosure, the scattering zone can be formed without any limitation on the order of the processes.

In another embodiment, according to a III-nitride semiconductor light-emitting device of the present disclosure, light extraction efficiency of the light-emitting device can be improved by various scattering angles.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a view of an example of a conventional III-nitride semiconductor light-emitting device.

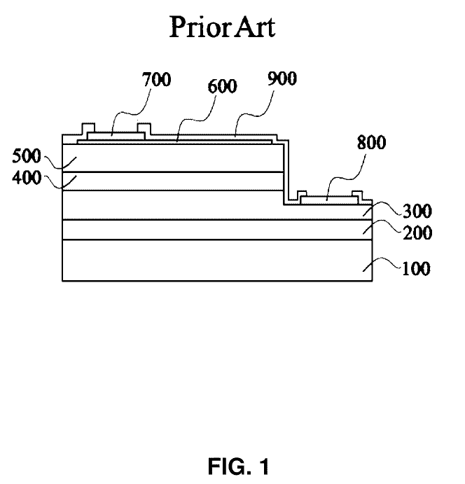

FIG. 2 is a view of one example of a semiconductor light-emitting device described in U.S. Pat. No. 6,657,236.

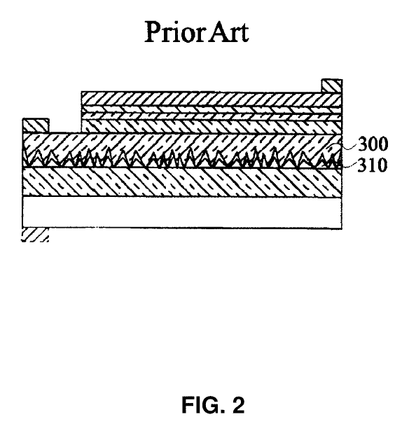

FIG. 3 is a view of another example of the semiconductor light-emitting device described in U.S. Pat. No. 6,657,236.

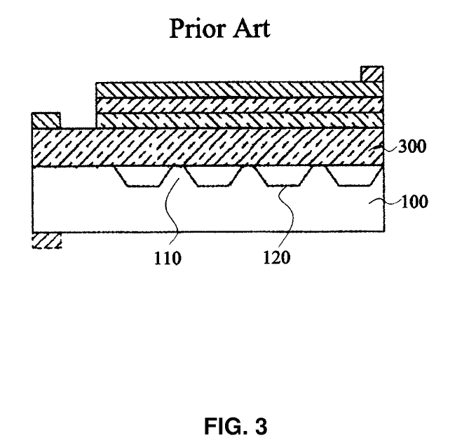

FIG. 4 is a view of an example of a method for fabricating a semiconductor light-emitting device described in U.S. Application No. 2008/121906.

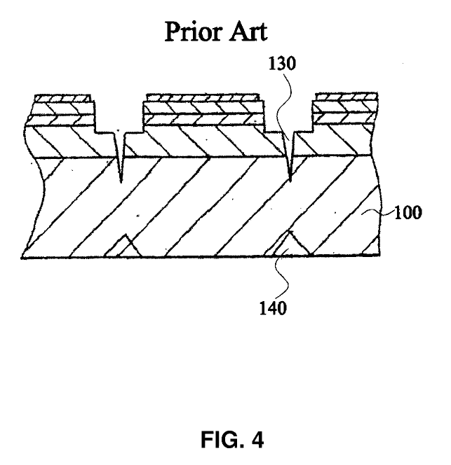

FIG. 5 is a view of an example of a method for fabricating a semiconductor light-emitting device described in Japanese Application No. 11-163403.

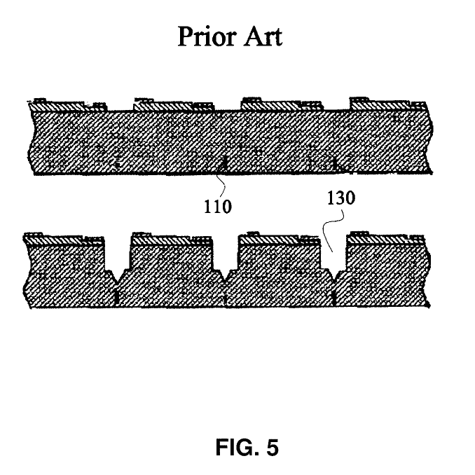

FIG. 6 is a view of an embodiment of a III-nitride semiconductor light-emitting device according to the present disclosure.

FIG. 7 is a view of one example of a substrate provided in the III-nitride semiconductor light-emitting device according to the present disclosure.

FIG. 8 is a view of another example of the substrate provided in the III-nitride semiconductor light-emitting device according to the present disclosure.

FIG. 9 is a view of a further example of the substrate provided in the III-nitride semiconductor light-emitting device according to the present disclosure.

FIG. 10 is a view of an embodiment of a method for fabricating a III-nitride semiconductor light-emitting device according to the present disclosure.

FIG. 11 is an SEM image of a substrate processed according to the present experimental example when viewed from the top.

FIG. 12 is an SEM image of a substrate in which scattering zones are formed at given intervals according to the present experimental example when viewed from the top.

FIG. 13 is an image of a III-nitride semiconductor light-emitting device including the substrate processed according to the present experimental example when viewed from the top.

Corresponding reference numerals indicate corresponding parts throughout the several views of the drawings.

### DETAILED DESCRIPTION

Hereinafter, the present disclosure will now be described in detail with reference to the accompanying drawings.

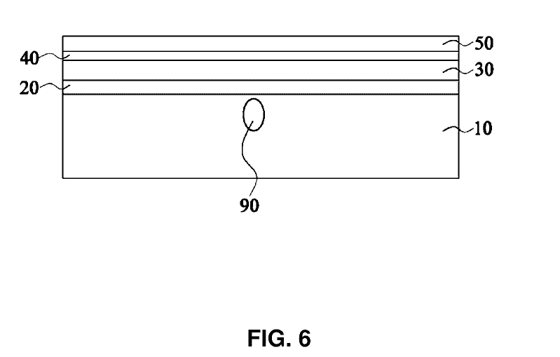

FIG. 6 is a view of an embodiment of a III-nitride semiconductor light-emitting device according to the present disclosure. The III-nitride semiconductor light-emitting device includes a substrate 10, a buffer layer 20 epitaxially grown on the substrate 10, an n-type III-nitride semiconductor layer 30 epitaxially grown on the buffer layer 20, an active layer 40 epitaxially grown on the n-type III-nitride semiconductor layer 30 and generating light by recombination of electrons and holes, a p-type III-nitride semiconductor layer 50 epitaxially grown on the active layer 40, and a scattering zone 90.

The substrate 10 may be a sapphire substrate.

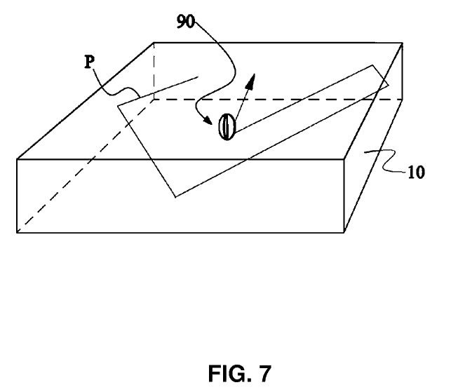

FIG. 7 is a view of an example of the substrate provided in the III-nitride semiconductor light-emitting device according to the present disclosure. A scattering zone 90 is formed in the substrate 10 to scatter the light generated in the active layer 40 (referring to FIG. 6). The scattering zone 90 is formed when an inner portion of the substrate 10 is transformed (e.g., when the sapphire of the sapphire substrate is transformed). Therefore, the scattering zone 90 can be formed in various sizes or shapes, and one scattering zone 90 can provide various scattering angles. The scattering zone 90 may be continuously formed by transversely or longitudinally crossing the space between the top and bottom surfaces of the substrate 10. P represents an example of a light path.

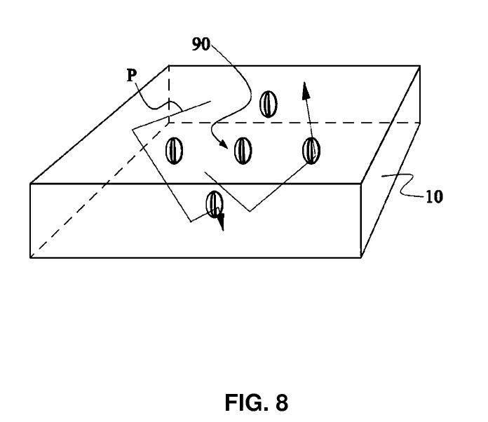

FIG. 8 is a view of another example of the substrate provided in the III-nitride semiconductor light-emitting device according to the present disclosure. A plurality of scattering zones 90 may be formed. The scattering zones 90 may be distributed irregularly or at given intervals. In some particular embodiments, the scattering zones 90 are formed at given intervals to evenly distribute the scattering zones 90. P represents another example of a light path.

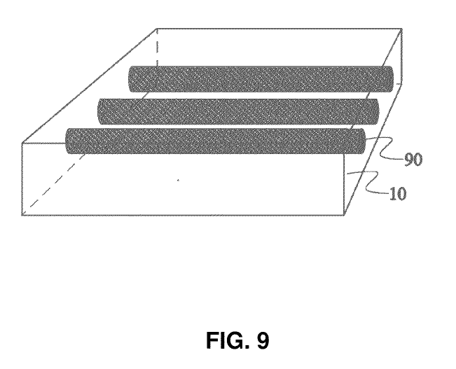

FIG. 9 is a view of a further example of the substrate provided in the III-nitride semiconductor light-emitting device according to the present disclosure. Scattering zones 90 are continuously formed at given intervals by transversely crossing the space between the top and bottom surfaces of the substrate 10.

Hereinafter, a method for fabricating a III-nitride semiconductor light-emitting device according to the present disclosure will now be described using a sapphire substrate as an example.

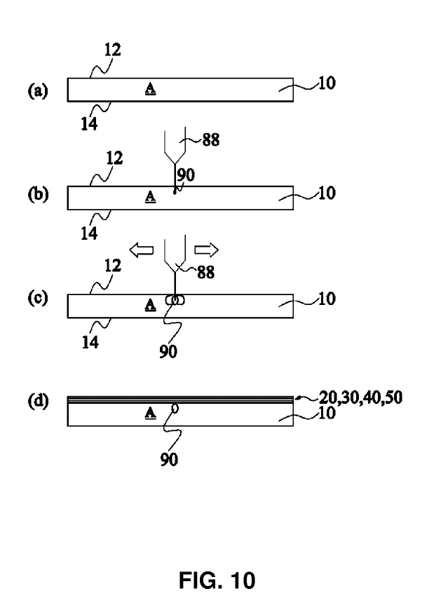

FIG. 10 is a view of an embodiment of the method for fabricating the III-nitride semiconductor light-emitting device according to the present disclosure.

A substrate 10 is prepared (referring to FIG. 10(a)).

A laser 88 is irradiated from a top surface 12 of the substrate 10 to the inside A of the substrate 12 in order to form a scattering zone 90 (referring to FIG. 10(b)). The laser 88 may be irradiated from a bottom surface 14 of the substrate 10. The size, shape, and the like of the scattering zone 90 may be changed according to the irradiation conditions of the laser 88. While the laser 88 is irradiated, the substrate 10 or the laser 88 is moved so that the scattering zone 90 can be continuously formed by transversely or longitudinally crossing the space between the top and bottom surfaces 12 and 14 of the substrate 10 (referring to FIG. 10(c)). For example, the laser 88 is focused on the inside A of the substrate 10. When the light-emitting device is divided into individual light-emitting devices, the bottom surface 14 of the substrate 10 may be polished to reduce the thickness of the substrate 10 to allow easier dividing. In some embodiments, the laser 88 is focused on the inside A of the substrate 10 to be adjacent to the top surface 12 in order to prevent the scattering zone 90 from being damaged or destroyed when polished.

A buffer layer 20, an n-type III-nitride semiconductor layer 30, an active layer 40, and a p-type III-nitride semiconductor layer 50 are grown on the top surface 12 of the substrate 10 (referring to FIG. 10(d)). The scattering zone 90 may be formed after the buffer layer 20, the n-type III-nitride semiconductor layer 30, the active layer 40 and the p-type III-nitride semiconductor layer 50 are grown on the top surface 12 of the substrate 10.

### Experimental Example

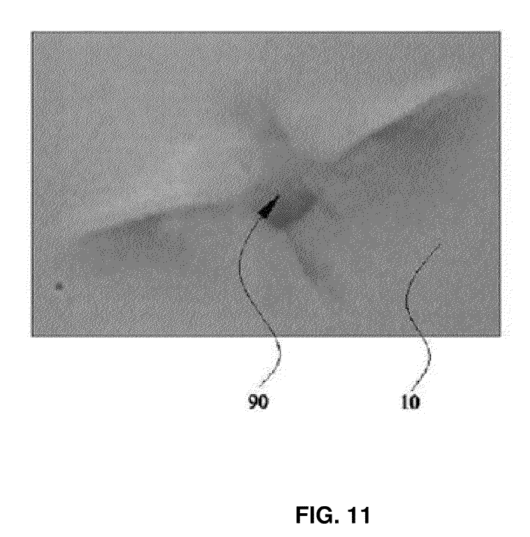

FIG. 11 is an SEM image of a substrate processed according to the present experimental example, when viewed from the top. A scattering zone 90 transformed by a laser was seen in the substrate 10. A surface damage of the substrate 10 was not detected.

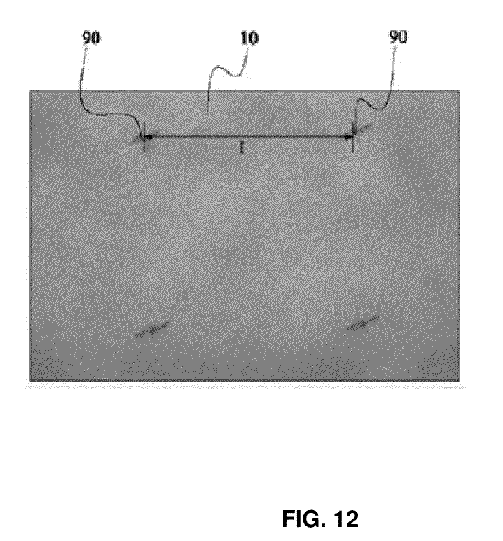

FIG. 12 is an SEM image of a substrate wherein scattering zones are formed at given intervals according to the present experimental example when viewed from the top. The scattering zones 90 were formed in the substrate 10 at intervals I of 300 μm.

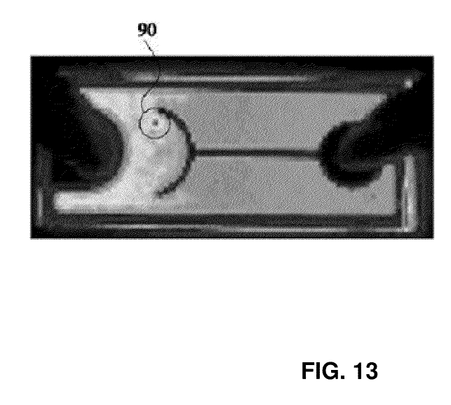

FIG. 13 is an image of a III-nitride semiconductor light-emitting device including the substrate processed according to the present experimental example when viewed from the top. A scattering zone 90 formed in the substrate 10 (referring to FIG. 6) scattered a large amount of light.

The substrate 10 was a plane substrate formed of sapphire having a thickness of 400 μm and a diameter of 2 inches.

A laser 88 was a UV pulse laser with a wavelength of 532 nm and a pulse of 7 ns. The laser 88 was focused at a depth of 130 μm from a top surface 12 of the substrate 10. The substrate 10 was processed using a micro-spot lens. The laser 88 was irradiated to form the scattering zones 90 at intervals of 300 μm (referring to FIGS. 10 to 12).

Hereinafter, variety examples of the present invention are explained.

(1) The III-nitride semiconductor light-emitting device wherein the scattering zone is a region formed by transformation of the substrate by a laser.

(2) The III-nitride semiconductor light-emitting device wherein the scattering zone is continuously formed crossing the inside of the substrate.

(3) The III-nitride semiconductor light-emitting device wherein the plurality of scattering zones are formed in the substrate.

(4) The III-nitride semiconductor light-emitting device wherein the substrate is formed of sapphire.

(5) The III-nitride semiconductor light-emitting device wherein the scattering zone is a region formed by transformation of the substrate by a laser.

(6) The III-nitride semiconductor light-emitting device wherein the substrate is formed of sapphire, and the scattering zone is formed when the substrate is transformed by a laser, and is formed at an upper portion of the inside of the substrate

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A III-nitride semiconductor light-emitting device, comprising:
a substrate with a scattering zone formed therein; and
a plurality of III-nitride semiconductor layers including a first III-nitride semiconductor layer formed over the substrate and having a first conductivity type, a second III-nitride semiconductor layer formed over the first III-nitride semiconductor layer and having a second conductivity type different from the first conductivity type, and an active layer disposed between the first III-nitride semiconductor layer and the second III-nitride semiconductor layer and generating light by recombination of electrons and holes.

2. The III-nitride semiconductor light-emitting device of claim 1, wherein the scattering zone is a region formed by transformation of the substrate by a laser.

3. The III-nitride semiconductor light-emitting device of claim 1, wherein the scattering zone is continuously formed crossing the inside of the substrate.

4. The III-nitride semiconductor light-emitting device of claim 1, wherein the plurality of scattering zones are formed in the substrate.

5. The III-nitride semiconductor light-emitting device of claim 1, wherein the substrate of sapphire.

6. The III-nitride semiconductor light-emitting device of claim 1, wherein the scattering zone is formed at an upper portion of the inside of the substrate.

7. The III-nitride semiconductor light-emitting device of claim 1, wherein the substrate is sapphire, and the scattering zone is a region formed by transformation of the substrate by a laser.

8. The III-nitride semiconductor light-emitting device of claim 7, wherein the scattering zone is formed at an upper portion of the inside of the substrate
